(19) United States
(12) Patent Application Publication
(10) Pub. No.: US 2005/0054198 A1
(43) Pub. Date: Mar. 10, 2005

(54) Apparatus of chemical vapor deposition

(76) Inventor: Pyung Yong Um, Surrey Bc (CA)

Correspondence Address: Norman P Soloway;Hayes Soloway, 130 West Cushing Street, Tucson, AZ, 85701, US

(21) Appl. No.: 10/494,556

(22) PCT Filed: Nov. 5, 2001
(86) PCT No.: PCT/KR01/01870

(51) Int. Cl. H01L 21/302; H01L 21/461

(52) U.S. Cl. 438/689

(57) ABSTRACT

Disclosed is an apparatus for chemical vapor deposition including: a dome-shaped upper chamber having a half-round surface or a curved surface of a predetermined angle; a shower head disposed in the upper chamber, for ejecting a reaction gas for film deposition straight or radially according to the shape of the upper chamber; a lower chamber sealed off from the upper chamber by way of an O-ring; a heater disposed at the center of the bottom surface of the lower chamber as a heat energy source for forming the films; and a nozzle for ejecting the reaction gas and preventing entrance of the reaction gas from the bottom of the heater. The apparatus ejects the reaction gas for film deposition straight or radially onto the surface of the wafer to secure films excellent in deposition uniformity and remarkably reduce the formation of products in the chamber.

### TECHNICAL FIELD

The present invention relates to an apparatus for chemical vapor deposition for depositing films on the surface of a wafer and, more particularly, to an improved apparatus for chemical vapor deposition capable of achieving films excellent in deposition uniformity and minimizing the formation of products in the chamber.

### BACKGROUND ART

With the tendency of semiconductor devices towards miniaturization with a light weight, the design-rule is greatly reducing and the RC delay designed by wiring has become an important factor that determines the operational speed of the semiconductor devices. Accordingly, the multi-layer wiring structure has been put to practical use. The number of metal wires necessary to the large integrated circuit devices such as microprocessor has increased from two or three to four or six, and more wires will be used with the higher degree of integration of the semiconductor devices in the future.

The wires are usually formed from tungsten (W) excellent in step coverage and conductivity and such tungsten layers are typically deposited by the chemical vapor deposition (CVD) method.

The fields of the CVD applications include: (1) the fabrication of wires having an electrical conductivity, such as polysilicon layer, Cu/Ti/TiN layer, Al, W or W-Six layer; (2) the deposition of oxide (SiO₂) layers used as an insulation layer between conductive layers from various chemicals; (3) the deposition of high dielectric films such as Si₃N₄, Ta₂O₅, BST, PZT, or Al₂O₃ used as a dielectric material for memory devices, including dynamic random access memory (DRAM) or flash memory; and (4) the process for depositing an oxide layer doped with impurities such as phosphorus (P) or boron (B) in order to reduce the step difference on the surface of the semiconductor substrate in performing the subsequent patterning step in the fabrication of semiconductor devices.

The CVD method for forming wiring or oxide layers on the semiconductor substrate includes a batch type CVD in which a plurality of wafers are simultaneously loaded before the process, and a single wafer type CVD in which the individual wafers are loaded one by one. The apparatus for single wafer type CVD has some strong points in the aspect of the process but is disadvantageous in that the deposition uniformity of the films depends on the structure of the apparatus for chemical vapor deposition.

The conventional apparatus for chemical vapor deposition provides films having a low deposition uniformity and causes the formation of undesired products in the chamber. The removal of the products from the chamber shortens the cleaning cycle of the chamber to cause a delay of the process. Furthermore, the products function as particles that deteriorate the reliability of the semiconductor devices and hence the yield.

### SUMMARY OF THE INVENTION

It is therefore an object of the present invention to provide an improved apparatus for chemical vapor deposition capable of solving the problems with the prior art.

It is another object of the present invention to provide an improved apparatus for chemical vapor deposition capable of enhancing the deposition uniformity of films deposited.

It is still another object of the present invention to provide an improved apparatus for chemical vapor deposition capable of minimizing the formation of products in the chamber.

It is further another object of the present invention to provide an improved apparatus for chemical vapor deposition capable of increasing the deposition yield.

It is still further another object of the present invention to provide an improved apparatus for chemical vapor deposition capable of solving the problem in regard to a shortened cleaning cycle of the chamber.

To achieve the objects of the present invention, there is provided an apparatus for chemical vapor deposition, which is used for deposition of films for forming wires or insulation layers on the surface of a wafer, the apparatus including: a dome-shaped upper chamber having a half-round surface or a curved surface of a predetermined angle; a shower head disposed in the upper chamber, for ejecting a reaction gas for film deposition straight or radially according to the shape of the upper chamber; a lower chamber sealed off from the upper chamber by way of an O-ring; a heater disposed at the center of the bottom surface of the lower chamber as a heat energy source for forming the films; and a nozzle for ejecting the reaction gas and preventing entrance of the reaction gas from the bottom of the heater.

### BRIEF DESCRIPTION OF THE DRAWINGS

Further objects and advantages of the invention can be more fully understood from the following detailed description taken in conjunction with the accompanying drawings, in which:

FIG. 1 is an overall cross-sectional view showing an apparatus for chemical vapor deposition in accordance with a preferred embodiment of the present invention;

FIG. 2 is a three-dimensional perspective showing an upper chamber of the apparatus for chemical vapor deposition;

FIG. 3 is a cross-sectional view showing the upper chamber of the apparatus for chemical vapor deposition;

FIG. 4 is a bottom plan view showing the upper chamber of the apparatus for chemical vapor deposition;

FIG. 5 is a three-dimensional perspective showing a lower chamber of the apparatus for chemical vapor deposition;

FIG. 6 is a cross-sectional view showing the lower chamber of the apparatus for chemical vapor deposition;

FIG. 7 is a bottom plan view showing the lower chamber of the apparatus for chemical vapor deposition;

FIG. 8 is a cross-sectional view showing a heater of the apparatus for chemical vapor deposition;

FIG. 9 is a plan view showing an inner heater of the apparatus for chemical vapor deposition;

FIG. 10 is a plan view showing an outer heater of the apparatus for chemical vapor deposition; and

FIG. 11 is a rear plan view of the outer heater of the apparatus for chemical vapor deposition.

### BEST MODE FOR CARRYING OUT THE INVENTION

Hereinafter, the present invention will be described in further detail by way of the accompanying drawings.

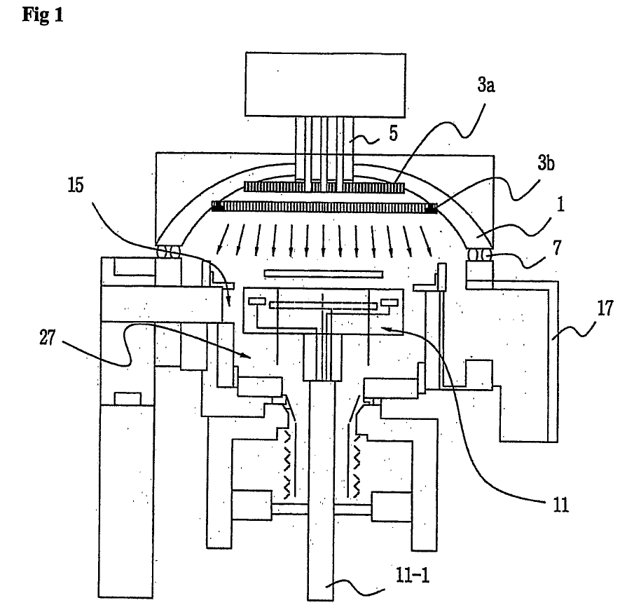

FIG. 1 is an overall cross-sectional view showing an apparatus for chemical vapor deposition in accordance with a preferred embodiment of the present invention.

Referring to FIG. 1, the apparatus for chemical vapor deposition comprises an upper chamber, a shower head disposed in the upper chamber, a lower chamber, and a heat source disposed in a defined region of the lower chamber, which components will be described in detail with reference to the following drawings.

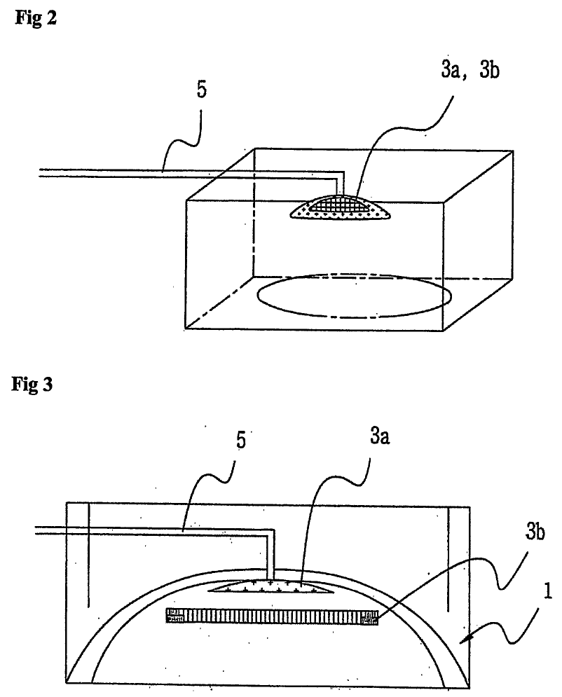

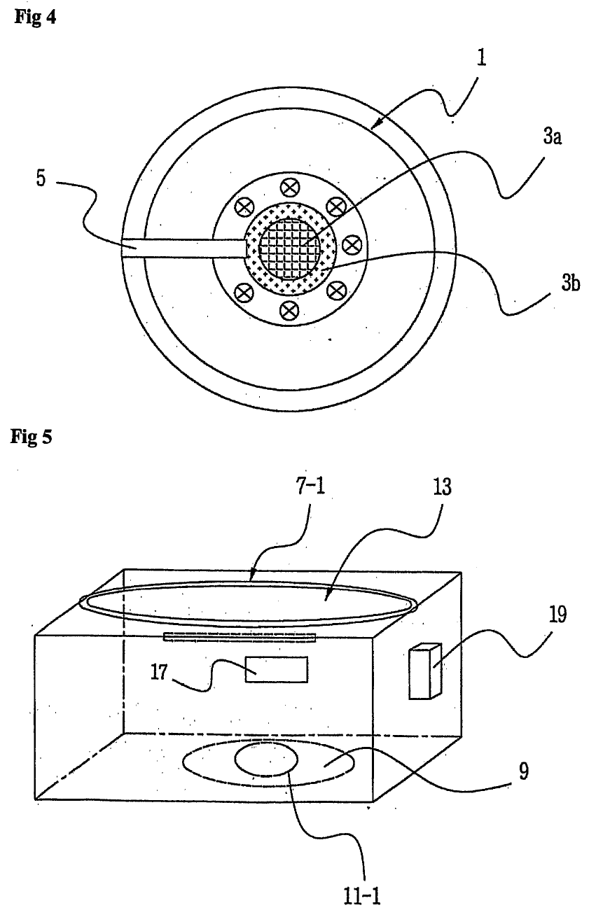

FIG. 2 is a three-dimensional perspective showing an upper chamber of the apparatus for chemical vapor deposition, FIG. 3 is a cross-sectional view showing the upper chamber of the apparatus for chemical vapor deposition, and FIG. 4 is a bottom plan view showing the upper chamber of the apparatus for chemical vapor deposition.

Referring to the figures, the upper chamber which has a half-round surface or a curved surface of a predetermined angle which comprises a sidewall 3, first and second shower heads 3a and 3b having holes of a defined shape, and a gas line 5 for introduction of an external gas.

The number, the diameter and the arrangement of the holes formed in the first and second shower heads 3a and 3b can be optimized to improve the deposition uniformity of films to be deposited. Namely, the size and the number of the holes of the first and second shower heads 3a and 3b are determined according to the characteristic of the films to be deposited. Preferably, the first and second shower heads 3a and 3b are apart from each other at a predetermined distance that optimizes the deposition uniformity of the films. Preferably, the plate of the first shower head 3a or the second shower head 3b is formed movable so as to maintain the optimized distance between the first and second shower heads 3a and 3b. The gas stream is ejected from the shower heads straight or radially according to the shape of the upper chamber, which enhances the deposition uniformity of the film deposited on the surface of the wafer.

The preferable material of the first and second shower heads 3a and 3b is nickel, or may be pure aluminum or oxidized aluminum depending on the material of the film to be deposited, i.e., the type of a remote plasma cleaning gas.

Now, a detailed description will be given to the construction of the first and second shower heads 3a and 3b through which the external gas is introduced into the chamber.

Supplied from the gas line 5, the gas passes through the first shower head 3a having a predetermined number of holes and then the second shower head 3b being apart from the first shower head 3a at a predetermined distance. The number of holes in the second shower head 3b is greater than that of holes in the first shower head 3a.

Accordingly, the plural holes formed in the first and second shower heads 3a and 3b make the external gas reach the surface of the wafer straight or radially according to the shape of the upper chamber, thereby enhancing the deposition uniformity of the film to be deposited. This secures films having excellent characteristics in the stoichiometric aspect and also improves the loading effect in the region having a high pattern density in comparison with a pattern-free planer in the wafer.

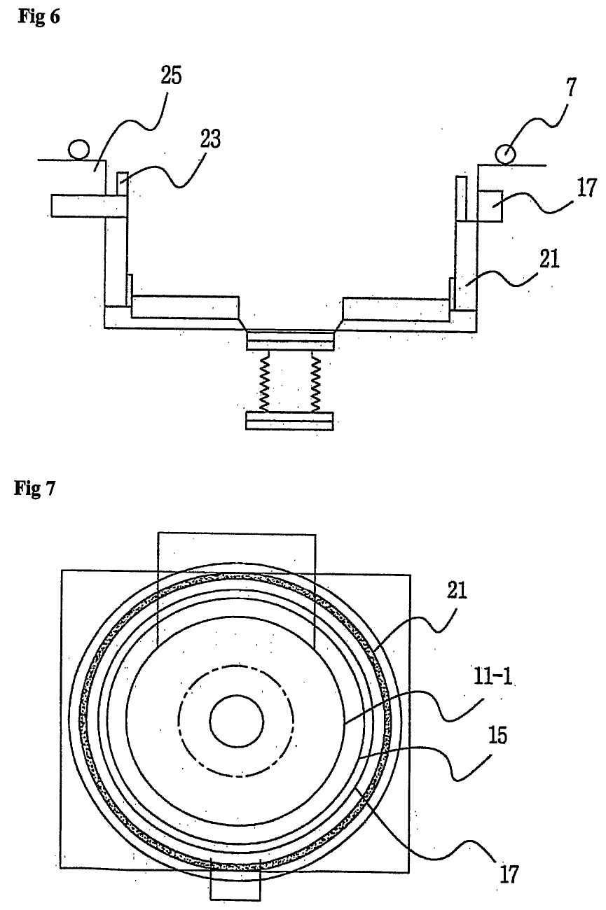

FIG. 5 is a three-dimensional perspective showing a lower chamber of the apparatus for chemical vapor deposition, FIG. 6 is a cross-sectional view showing the lower chamber of the apparatus for chemical vapor deposition, and FIG. 7 is a bottom plan view showing the lower chamber of the apparatus for chemical vapor deposition.

Referring to the figures, the lower chamber comprises a recess 7-1 which is formed on the top of the lower chamber to receive an O-ring for maintaining vacuum sealing, and a cylindrical chamber sidewall 21 which is formed from the top of the chamber to have a predetermined volume. A taping chamber 9 extending from the bottom of the lower chamber in a predetermined height tapers down towards the bottom of the lower chamber at a predetermined angle. At the center of the bottom of the lower chamber is formed a hole 11-1 having a defined shape, in which a heater 11 used as a heat source of the present invention will be positioned. A slot 13 is formed on the one side of the cylindrical chamber for loading/unloading the wafer. An asymmetric vacuum guide 15 which is formed on the cylindrical chamber sidewall 21 maintains the vacuum state in the chamber and guides the gas stream radially to enhance the deposition uniformity of the film. A vacuum port 17 coupled to the vacuum guide 15 is formed on the opposite side to the wafer-loading/unloading position, and a gate port 19 is formed in a defined region of the cylindrical chamber sidewall 21 for measuring the inner condition of the lower chamber.

Inner and outer vacuum plates 23 and 25 maintain the inside of the chamber under vacuum and guide the gas stream during the process. A nitrogen (N₂) nozzle 27 prevents entrance of the gas from the bottom of the heater. The inner vacuum plate 23 has a nitrogen gas slot for controlling the flow passage of the nitrogen nozzle 27.

To maintain the vacuum condition between the upper and lower chambers, a single O-ring may be used as well as the double O-ring 7.

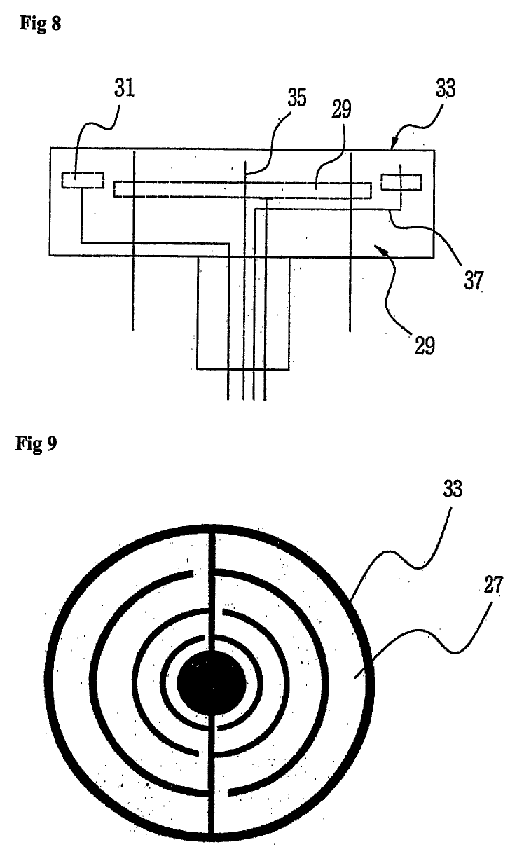

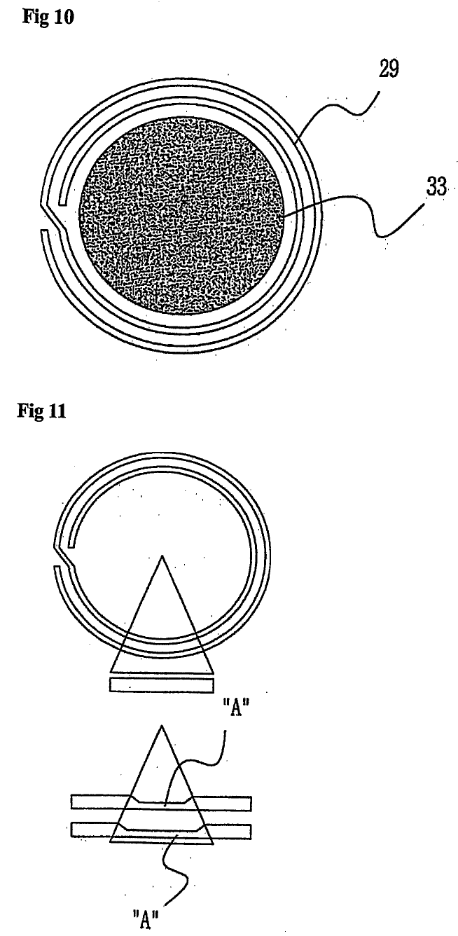

FIG. 8 is a cross-sectional view showing a heater of the apparatus for chemical vapor deposition, FIG. 9 is a plan view showing an inner heater of the apparatus for chemical vapor deposition, and FIG. 10 is a plan view showing an outer heater of the apparatus for chemical vapor deposition.

Referring to the figures, the inner heater 29 is slightly smaller in diameter than the wafer 33 and controls the internal temperature of the chamber. The heating element of the inner heater 29 is formed from molybdenum (Mo) or ceramic.

A heater block that functions as the outer heater 31 is disposed at a distance of about 2 to 10 mm out from the outer diameter of the wafer, such a close distance from the sidewall of the chamber leads to a great loss of heat. It is thus required to control the temperature of the outer heater 31 in order to maintain a uniform temperature on the surface of the wafer. The material of the heating element for the outer heater 31 may be molybdenum (Mo) or ceramic. Preferably, the heater block, which surrounds the heating element and transfers the heat from the heater to a susceptor 33, is formed from a ceramic material such as aluminum nitride (AIN). Unevenness is formed from a defined pattern on the surface of the susceptor 33 so as to prevent a sliding of the wafer loaded.

Preferably, the lift pin for loading/unloading the wafer on the top of the heater is formed from a ceramic material such as Al₂O₃.

Inner and outer heat couplers 35 and 37 are disposed at the center and the edge of the heater, respectively, for controlling the internal temperature of the chamber.

FIG. 11 is a rear plan view of the outer heater of the apparatus for chemical vapor deposition.

Referring to the figure, the heating element is formed at the valve part that lets the wafer in and out, in which portion a greater loss of heat occurs compared to the other portions to make the film thinner. To prevent such a loss of heat at the portion, the heating element (reference symbol “A”) is formed thinner than the other portions to have a higher electrical resistance.

Accordingly, the heater of the apparatus for chemical vapor deposition according to the present invention is thinner in an isosceles triangle formed with the diameters of the slot valve based on the center of the heater as congruent sides. The controllable temperature of the heater is in the range from about 300 to 850° C. The heater is a heat source for supplying a heat activation energy to form films in the present invention and comprises a heating element for converting an externally applied electrical energy to a heat energy. The heater may comprise a portion formed from a ceramic material (AIN or Al₂O₃) that surrounds the heating element, and a portion disposed at a defined region in the thermal couple heater capable of measuring the internal temperature of the heater. The heater has such a required number of heat couplers as to optimize the deposition uniformity of the temperature on the surface of the heater.

The surface on the top of the heater on which the wafer is placed is called “susceptor”, which comprises a susceptor guide on which the wafer is mounted, and a lift pin for moving the wafer.

Now, a description will be given to different embodiments of a method for fabricating various films of semiconductor devices using the apparatus for chemical vapor deposition as constructed above.

First, in the case of using a single reaction gas in the fabrication of films, the reaction gas is introduced into the chamber through the shower heads 3a and 3b.

For example, when the SiH₄ or Si₂H₆ gas is fed into the chamber with the internal temperature of the chamber controlled at 450 to 650° C., amorphous or polycrystalline silicon films are deposited by the low pressure chemical vapor deposition (LPCVD).

Alternatively, when the SiH₄ or Si₂H₆ gas is fed into the chamber at the internal temperature of the chamber at 450 to 650° C. and the pressure of less than 10E-5 Torr, half-round silicon grains are selectively formed.

Second, in the case of using at least two reaction gases in the fabrication of films, a first reaction gas and a second reaction gas are separately or simultaneously introduced into the chamber through the shower heads 3a and 3b.

For example, a nitride (Si₃N₄) film is formed from NH₃ and SiH₂Cl₂ by introducing N₂O and then simultaneously NH₃ and SiH₂Cl₂ into the chamber with the internal temperature of the chamber at 500 to 800° C. and the pressure of less than 300 Torr.

A nitride film is formed from NH₃ and SiH₄ by introducing N₂O and then simultaneously NH₃ and SiH₄ into the chamber with the internal temperature of the chamber at 500 to 800° C. and the pressure of less than 300 Torr.

A nitride film is formed from NH₃ and SiCl₄ by introducing N₂0 and then simultaneously NH₃ and SiCl₄ into the chamber with the internal temperature of the chamber at 500 to 800° C. and the pressure of less than 300 Torr.

A nitride film is formed from NH₃ and SiCl₆ by introducing N₂O and then simultaneously NH₃ and SiCl₆ into the chamber with the internal temperature of the chamber at 500 to 800° C. and the pressure of less than 300 Torr.

Alternatively, an oxide (SiO₂) film is formed from O₂ and SiH₄ by introducing O₂ and then simultaneously O₂ and SiH₄ into the chamber with the internal temperature of the chamber at 300 to 800° C. and the pressure of less than 300 Torr.

An oxide film is formed from N₂O and SiH₂C1₂ by introducing N₂O and then simultaneously N₂O and SiH₂Cl₂ into the chamber with the internal temperature of the chamber at 300 to 800° C. and the pressure of less than 300 Torr.

An oxide film is formed from N₂O and SiH₄ by introducing N₂O and then simultaneously N₂O and SiH₄ into the chamber with the internal temperature of the chamber at 300 to 800° C. and the pressure of less than 300 Torr.

Fourth, in the case of using at least three reaction gases to form a CVD film, one or two gases are first introduced before the rest one or two gases.

As described above, the apparatus for chemical vapor deposition to form a film on the surface of the wafer comprises an upper chamber which has a dome shape with a half-round surface or a curved surface of a predetermined angle so as to guide the reaction gas for film deposition ejected straight or radially onto the surface of the wafer.

The heater for controlling the internal temperature of the chamber has a double structure so as to minimize a loss of heat from the sidewall of the chamber, thereby enhancing the deposition uniformity of the films.

The heating element of the outer heater is thinner than the other portions to enhance the deposition uniformity of the films deposited on the surface of the wafer as well as the stoichiometric characteristic of the films.

Furthermore, the nitrogen gas is introduced through the nitrogen nozzle to prevent entrance of the reaction gas from the bottom of the heater, which reduces the formation of products in the chamber and thereby extends the cleaning cycle of the chamber with improved loading effect.

While this invention has been described in connection with what is presently considered to be the most practical and preferred embodiment, it is to be understood that the invention is not limited to the disclosed embodiments, but, on the contrary, is intended to cover various modifications and equivalent arrangements included within the spirit and scope of the appended claims.

1. An apparatus for chemical vapor deposition, which is used for deposition of films for forming wires or insulation layers on the surface of a wafer, the apparatus comprising:
a dome-shaped upper chamber having a half-round surface or a curved surface of a predetermined angle;
a shower head disposed in the upper chamber, for ejecting a reaction gas for film deposition straight or radially according to the shape of the upper chamber;
a lower chamber sealed off from the upper chamber by way of an O-ring;
a heater disposed at the center of the bottom surface of the lower chamber as a heat energy source for forming the films; and
a nozzle for ejecting the reaction gas and preventing entrance of the reaction gas from the bottom of the heater.

2. The apparatus for chemical vapor deposition as claimed in claim 1, wherein the lower chamber has a tapering cylindrical form with a predetermined volume from the top of the chamber, the lower chamber tapering down to the bottom from a predetermined height at a predetermined angle, the lower chamber comprising: a slot formed on the one side of the chamber for loading/unloading the wafer; an asymmetric vacuum guide formed on the sidewall of the chamber to maintain vacuum in the chamber and guide a radial gas stream; a nitrogen gas slot for providing the flow passage of a nitrogen gas ejected from a nitrogen nozzle; and a vacuum port formed on the opposite side to a wafer loading/unloading position.

3. The apparatus for chemical vapor deposition as claimed in claim 1, wherein the shower head comprises:
a first shower head for introducing the reaction gas externally applied; and
a second shower head for secondly introducing the reaction gas after the first shower head, the second shower head being apart from the first shower head at a predetermined distance so as to enhance the deposition uniformity of films to be deposited, the second shower head having a larger number of holes than the first shower head.

4. The apparatus for chemical vapor deposition as claimed in claim 3, wherein the first shower head or the second shower head is formed movable so as to maintain the predetermined distance between the first and second shower heads.

5. The apparatus for chemical vapor deposition as claimed in claim 1, wherein the heater has a heating element for converting an externally applied electrical energy to a heat energy.

6. The apparatus for chemical vapor deposition as claimed in claim 5, wherein the heating element of the heater is formed from molybdenum (Mo) or ceramic (Sic).

7. The apparatus for chemical vapor deposition as claimed in claim 1, wherein the heater consists of aluminum nitride(AIN).

8. The apparatus for chemical vapor deposition as claimed in claim 1, wherein the shower head is formed from pure aluminum or oxidized aluminum depending on the material of films to be deposited.

9. The apparatus for chemical vapor deposition as claimed in claim 1, wherein a single or double O-ring is formed between the upper and lower chambers so as to maintain the vacuum state between the upper and lower chambers.

10. The apparatus for chemical vapor deposition as claimed in claim 1, wherein the heating element of an outer heater is thinner than the other portions.

11. The apparatus for chemical vapor deposition as claimed in claim 1, wherein the heater has a double structure comprising inner and outer heaters so as to prevent a loss of heat from the sidewall of the chamber.
